(19) United States
(12) Patent Application Publication
(10) Pub. No.: US 2023/0367200 A1
(43) Pub. Date: Nov. 16, 2023

(54) BLANK MASK AND PHOTOMASK USING THE SAME

(71) Applicant: SK enpulse Co., Ltd., Pyeongtaek-si (KR)

(72) Inventors: Seong Yoon KIM, Seoul (KR); Sung Hoon SON, Seoul (KR); Min Gyo JEONG, Seoul (KR); Inkyun SHIN, Seoul (KR); Suk Young CHOI, Seoul (KR); Hyung-ju LEE, Seoul (KR); Suhyeon KIM, Seoul (KR)

(73) Assignee: SK enpulse Co., Ltd., Pyeongtaek-si (KR)

(21) Appl. No.: 18/312,942

(22) Filed: May 5, 2023

(30) Foreign Application Priority Data
May 13, 2022 (KR) 10-2022-0058833

(51) Int. Cl. G03F 1/32; G03F 1/80; G03F 1/54

(52) U.S. Cl. CPC G03F 1/32; G03F 1/80; G03F 1/54

(57) ABSTRACT

A blank mask includes a light-transmitting substrate; and a light-shielding film on the light-transmitting substrate. The light-shielding film includes a transition metal and oxygen, and a scum formation time required to generate scum is 120 minutes or more when light with a wavelength of 172 nm and an intensity of 10 kJ/cm² is applied on the light-shielding film.

### CROSS-REFERENCE TO RELATED APPLICATIONS

This application claims the benefit under 35 USC § 119(a) of Korean Patent Application No. 10-2022-0058833, filed on May 13, 2022, in the Korean Intellectual Property Office, the entire disclosure of which is incorporated herein by reference for all purposes.

### BACKGROUND

### 1. Field

The following description relates to a blank mask and a photomask using the same.

### 2. Description of Related Art

Due to the increasing circuit integration in semiconductor devices, it is necessary to achieve miniaturization of circuit patterns in semiconductor devices. For this reason, the importance of improving lithography techniques, which are the technology used for developing a circuit pattern using a photomask on a wafer surface, is becoming more prominent.

To order to develop a miniaturized circuit pattern on a wafer surface, the exposure light source used in an exposure process to develop the circuit pattern needs to have a short wavelength. Examples of exposure light sources that have recently been used include an ArF excimer laser (a wavelength of 193 nm) and the like.

Examples of photomasks include binary masks and phase shift masks. A binary mask has a structure in which a light-shielding layer pattern is formed on a light-transmitting substrate. In a binary mask, a transmissive part that does not include a light-shielding layer transmits the exposure light, and a light-shielding part that includes the light-shielding layer blocks the exposure light, thereby exposing a pattern on a resist film on the wafer surface. However, as the pattern of the binary mask is miniaturized, diffraction of light is likely to occur at the edge of the transmissive part during the exposure process. Such diffraction of light may interfere with the ability to form fine patterns.

Examples of phase shift masks include Levenson-type phase shift masks, outrigger-type phase shift masks, and half-tone type phase shift masks. Among these different types of phase shift masks, a half-tone type phase shift mask has a configuration in which a semi-transmissive film pattern is formed on a light-transmitting substrate. In a half-tone phase shift mask, a transmissive part that does not include a semi-transmissive layer transmits exposure light, and a semi-transmissive part that includes the semi-transmissive layer transmits attenuated exposure light. There is a phase difference between the attenuated exposure light and the exposure light transmitted through the transmissive part. Due to this phase difference, the light diffracted at an edge of the transmissive part is offset by the exposure light transmitted through the semi-transmissive part. As a result, the phase shift mask allows forming of more sophisticated fine patterns on wafer surfaces.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject.

In one or more general aspects, a blank mask includes a light-transmitting substrate; and a light-shielding film on the light-transmitting substrate. The light-shielding film includes a transition metal and oxygen, and a scum formation time required to generate scum is 120 minutes or more when light with a wavelength of 172 nm and an intensity of 10 kJ/cm² is applied on the light-shielding film.

A surface of the light-shielding film may include transition metal content in an amount of 30 or more and 50 or less atomic percent.

A surface of the light-shielding film may include oxygen content in an amount of 35 or more and 55 or less atomic percent.

The light-shielding film may include a first light-shielding layer, and a second light-shielding layer on the first light-shielding layer. An etching rate of the second light-shielding layer measured by etching with argon gas may be 0.4 Å/s or more and 0.5 Å/s or less.

An etching rate of the first light-shielding layer measured by etching with argon gas may be 0.56 Å/s or more.

An etching rate of the light-shielding film measured by etching with chlorine-based gas may be 1.3 Å/s or more.

The light-shielding film may include a first light-shielding layer, and a second light-shielding layer on the first light-shielding layer, The second light-shielding layer may include transition metal content in an amount of 50 or more and 80 or less atomic percent and oxygen content in an amount of 10 or more atomic percent.

The transition metal may include one or more selected from the group consisting of: scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), lanthanum (La), hafnium (Hf), tantalum (Ta), tungsten (W), rhenium (Re), osmium (Os), iridium (Ir), platinum (Pt), gold (Au), mercury (Hg), actinium (Ac), rutherfordium (Rf), dubnium (db), seaborgium (Sg), bohrium (Bh), hassium (Hs), meitnerium (Mt), darmstadtium (Ds), roentgenium (Rg), ununbium (Uub), and a combination thereof.

The light-shielding film may include a first light-shielding layer, and a second light-shielding layer on the first light-shielding layer. A ratio of a thickness of the second light-shielding layer to a thickness of the light-shielding film may be in a range of 0.05 or more and 0.15 or less.

In another general aspect, a photomask is obtained from a blank mask as described above. The photomask may include the light-transmitting substrate; and the light-shielding pattern film on the light-transmitting substrate. The light-shielding pattern film may include a transition metal and oxygen. The scum formation time required to generate scum may be 120 minutes or more.

In yet another general aspect, a method of manufacturing a semiconductor device involves: disposing a light source, a photomask, and a semiconductor wafer coated with a resist film; selectively exposing the semiconductor wafer to light from the light source through the photomask; and developing a pattern on the semiconductor wafer.

The photomask may include a light-transmitting substrate and a light-shielding pattern film disposed on the light-transmitting substrate.

The light-shielding pattern film may include a transition metal and oxygen, and a scum formation time required to generate scum may be 120 minutes or more when light with a wavelength of 172 nm and an intensity of 10 kJ/cm² is applied to the light-shielding pattern film.

Other features and aspects will be apparent from the following detailed description, the drawings, and the claims.

### BRIEF DESCRIPTION OF THE DRAWINGS

FIG. 1 is a diagram illustrating an example of a blank mask according to one or more embodiments.

FIG. 2 is a diagram illustrating an example of a blank mask according to additional embodiments of the present disclosure.

FIG. 3 is a diagram illustrating an example of a blank mask according to additional embodiments.

FIG. 4 is a diagram illustrating an example of a photomask according to additional embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, terms such as “about” and “substantially” are used to indicate a corresponding numerical value or a value approximating it when a unique allowable manufacturing or material error is present, and prevent accurate or absolute numerical values, which are presented to help the understanding of embodiments, from being unfairly used by unscrupulous infringers. Such terms may encompass quantitative variations within 95% of the value, 98% of the value, or 99% of the value, for example.

Throughout the specification, the term “a combination thereof” included in an expression of the Markush form refers to a mixture or combination of one or more elements selected from the group consisting of elements described in the Markush form and should be understood as at least one selected from the group consisting of the elements.

Throughout the specification, the expression “A and/or B” should be understood as “A,” “B,” or “A and B.” The phrases “at least one of A, B, and C”, “at least one of A, B, or C′, and the like are intended to have disjunctive meanings, and these phrases “at least one of A, B, and C”, “at least one of A, B, or C′, and the like also include examples where there may be one or more of each of A, B, and/or C (e.g., any combination of one or more of each of A, B, and C), unless the corresponding description and embodiment necessitate such listings (e.g., “at least one of A, B, and C”) to be interpreted to have a conjunctive meaning.

Terms such as “first,” “second,” “A,” and “B” are used to distinguish one element from another unless otherwise described.

Throughout the specification, it should be understood that when B is referred to as being located on A, B is located adjacent to A or is located on A with another layer interposed therebetween, and B is not limited to being in contact with a surface of A.

Throughout the specification, singular forms are intended to include plural forms as well, unless the context clearly indicates otherwise.

When a light-shielding pattern film to which a transition metal is applied is exposed to exposure light, the transition metal may become ionized, and the ionized metal may migrate to a different location. When the light-shielding pattern film is used in a long-term exposure process, the migration of ions of the transition metal may have an accumulative impact, thus causing a substantial deformation of the light-shielding pattern film. The substantial deformation of the light-shielding pattern film may degrade the resolution of the photomask. In particular, as the line width of a patterned light-shielding film decreases, the pattern deformation on the resolution of the photomask may become more pronounced.

The inventors of the present disclosure have completed the present disclosure based on a confirmation that a blank mask has excellent light stability (light resistance, i.e., anti-oxidation from light) characteristics, and a photomask patterned from the blank mask has a stable resolution even when the photomask is used repeatedly in exposure processes by controlling a time required to generate scum in a light-shielding film by emitting high-energy light.

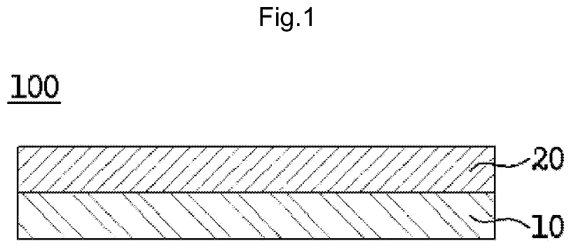

FIG. 1 is a diagram illustrating an example of a blank mask according to one or more embodiments of the present disclosure. An example of a blank mask is described below with reference to FIG. 1.

A blank mask 100 includes a light-transmitting substrate 10, and a light-shielding film 20 disposed on the light-transmitting substrate 10.

The material of the light-transmitting substrate (transparent substrate) 10 is not limited as long as it is transparent as to transmit the exposure light and is capable of being applied to the blank mask 100. Specifically, the transmittance of the light-transmitting substrate 10 for exposure light having a wavelength of 193 nm may be 85% or more. The transmittance may be 87% or more. The transmittance may be 99.99% or less. For example, a synthetic quartz substrate may be used as the light-transmitting substrate 10. In such a case, the light-transmitting substrate 10 may suppress the attenuation of light passing through the light-transmitting substrate 10.

In addition, the optical distortion of the blank mask 100 may be suppressed by adjusting surface characteristics such as flatness and roughness of the light-transmitting substrate 10.

The light-shielding film 20 may be positioned on a top side of the light-transmitting substrate 10.

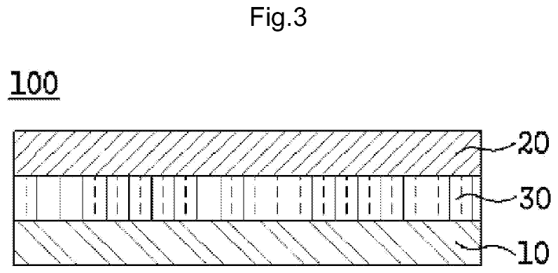

The light-shielding film 20 may block at least a portion of the exposure light incident on a bottom side of the light-transmitting substrate 10. In examples in which a phase shift film 30 (see FIG. 3) and the like are positioned between the light-transmitting substrate 10 and the light-shielding film 20, the light-shielding film 20 may be used as an etching mask in the etching process of the phase shift film 30 into a pattern.

According to an example, the light-shielding film 20 includes a transition metal and oxygen.

### Composition of Surface of Light-Shielding Film

According to an example, the surface of the light-shielding film 20 has a transition metal atom content in an amount of 30 at % to 50 at % (atomic percent).

In this example, the amount of the transition metal in the surface of the light-shielding film 20 may be controlled. By controlling the amount of the transition metal, the number of transition metal atoms directly exposed to the exposure light may be reduced in order to suppress the formation of defects originating from the light-shielding film 20. In this case, an etching rate of the surface of the light-shielding film 20 may be suppressed from increasing excessively while dry-etching is performed on the light-shielding film 20.

The transition metal may be one or more metals selected from the group consisting of scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), lanthanum (La), hafnium (Hf), tantalum (Ta), tungsten (W), rhenium (Re), osmium (Os), iridium (Ir), platinum (Pt), gold (Au), mercury (Hg), actinium (Ac), rutherfordium (Rf), dubnium (db), seaborgium (Sg), bohrium (Bh), hassium (Hs), meitnerium (Mt), darmstadtium (Ds), roentgenium (Rg), and ununbiium (Uub). The transition metal may be one or more metals selected from the group consisting of chromium (Cr), tantalum (Ta), titanium (Ti), and hafnium (Hf). The transition metal may be a single metal selected from the group consisting of Cr, Ta, Ti, and Hf.

The atomic percentage amount of the transition metal in the surface of the light-shielding film 20 may be 50 at % or less. The amount of the transition metal may be 45 at % or less. The amount of the transition metal may be 40 at % or less. The amount of the transition metal may be 30 at % or more. The amount of the transition metal may be 35 at % or more. In this case, the light-shielding film 20 may have a stable light extinction property and improved light stability (light resistance, i.e., anti-oxidation from light) characteristic.

In an embodiment, a degree of oxidation of the surface of the light-shielding film 20 may be controlled. Accordingly, the reactivity of the transition metal to light may be reduced, and the transition metal may be prevented from being ionized and separated from the surface of the light-shielding film 20.

An amount of oxygen atoms that are present in the surface of the light-shielding film 20 may be 35 at % or more. The amount of oxygen atoms may be 40 at % or more. The amount of oxygen atoms may be 45 at % or more. The amount of oxygen may be 55 at % or less. The amount of oxygen may be 52 at % or less. The amount of oxygen may be 50 at % or less. In this case, it is possible to provide a light-shielding film in which the migration of a transition metal is suppressed during the exposure process.

An amount of nitrogen atoms in the surface of the light-shielding film 20 may be 1 at % or more. The amount of nitrogen atoms may be 2 at % or more. The amount of nitrogen atoms may be 10 at % or less.

An amount of carbon atoms in the surface of the light-shielding film 20 may be 5 at % or more. The amount of carbon atoms may be 10 at % or more. The amount of carbon atoms may be 25 at % or less. The amount of carbon atoms may be 20 at % or less.

The amount of each element in the surface of the light-shielding film 20 may be measured by an X-ray photoelectron spectroscopy (XPS) analyzer. For example, the amount of each element of each film may be measured by a K-alpha model manufactured by Thermo Scientific Inc.

### Light Stability Property of Light-Shielding Film

When light with a wavelength of 172 nm and an intensity of 10 kJ/cm² is emitted on the light-shielding film 20, the scum formation time required to generate scum is 120 minutes or more.

The scum is a defect derived from the light-shielding film 20. The scum includes a transition metal compound.

The time required to generate scum is a parameter affected by not only the amount of the transition metal on the surface of the light-shielding film 20 but also the grain structure of the transition metal. Specifically, when the crystallization of the transition metal occurs in the light-shielding film 20, a crystal grain boundary may form on the surface of the light-shielding film 20. The crystal grain boundary may be relatively weak in terms of a bond between the atoms of the transition metal and high in terms of reactivity, compared to other regions. That is, the light stability (light resistance, i.e., anti-oxidation from light) characteristic of a light-shielding film to which the above amount of the transition metal is applied may vary according to the grain structure of the transition metal in the light-shielding film.

According to one embodiment, the composition of the surface of the light-shielding film 20 and the scum formation time required to generate scum in the light-shielding film may be controlled. Accordingly, the light stability (light resistance, i.e., anti-oxidation from light) property of the light-shielding film 20 can be improved by adjusting the density of the grain boundary on the surface of the light-shielding film 20.

A measuring method for the length of time required to generate scum in the light-shielding film 20 will be described below. To easily identify the scum, a transmission pattern with a constant line width is formed in the light-shielding film 20. Thereafter, light with a wavelength of 172 nm and an intensity of 10 kJ/cm² is emitted on the surface of the light-shielding film 20 using a UV exposure light accelerator. During the emission of the light, an image on the surface of the light-shielding film 20 is measured by a scanning electron microscope (SEM) at intervals of 30 minutes to check whether scum is formed. Light is emitted repeatedly in the same manner until scum is observed.

When light with a wavelength of 172 nm and an intensity of 10 kJ/cm² is emitted on the light-shielding film 20, the scum formation time required to generate scum may be 120 minutes or more. The scum formation time may be 150 minutes or more. The scum formation time may be 300 minutes or less. The scum formation time may be 200 minutes or less. In this case, the density of the grain boundary on the surface of the light-shielding film 20 may be further reduced to further improve the light-shielding characteristics of the light-shielding film 20.

### Etching Characteristics of Light-Shielding Film

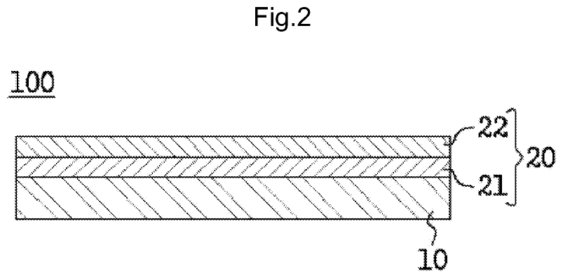

FIG. 2 is a diagram illustrating an example of a blank mask according to the present disclosure. A blank mask 100 will be described below with reference to FIG. 2.

The blank mask 100 includes a light-shielding film 20 and a light-transmitting substrate 10. In this example, the light-shielding film 20 includes a first light-shielding layer 21, and a second light-shielding layer 22 disposed on the first-light shielding layer 21. The first-light shielding layer 21 is disposed on the light-transmitting substrate 10.

An etching rate of the second light-shielding layer 22 measured while using argon gas as a gaseous etchant may be 0.4 Å/s or more and 0.5 Å/s or less.

Dry etching performed by applying argon gas as an etchant corresponds to a physical etching process that does not substantially involve a chemical reaction between the etchant and the light-shielding film 20. Thus, the etching rate measured using argon gas as an etchant is independent of the composition and chemical reactivity of each layer in the light-shielding film 20, and is considered a parameter that can effectively reflect the grain boundary density of each layer.

According to one embodiment, an etch rate of the second light-shielding layer 22 measured by etching the second light-shielding layer 22 using argon gas may be controlled. By controlling the etch rate, it is possible to adjust the density of a grain boundary on the light-shielding film 20, and effectively suppress the ionization and migration of transition metal ions caused by exposure light.

An example of a method of measuring the etching rate of the first light-shielding layer 21 and the second light-shielding layer 22 during the etching of these layers with argon gas as an etchant will be described below.

First, the thicknesses of the first light-shielding layer 21 and the second light-shielding layer 22 are measured by a transmission electron microscope (TEM). Specifically, a sample is prepared by processing a blank mask 100 to have a dimension of 15 mm in width and 15 mm in length. A surface of the sample is treated by focused ion beams (FIBs). The surface-treated sample is placed in a TEM image measurement device, and a TEM image of the sample is obtained. The thicknesses of the first light-shielding layer 21 and the second light-shielding layer 22 are calculated from the TEM image of the sample. As an example, the TEM image may be obtained through a JEM-2100F HR model manufactured by JEOL Ltd.

Thereafter, the first light-shielding layer 21 and the second light-shielding layer 22 of the sample are etched with argon gas as a gaseous etchant, and the etching time required to etch each of these layers is measured. Specifically, the etching time required to etch each of these layers is measured by placing the sample in an X-ray photoelectron spectroscopy (XPS) measurement device and etching a central region having a size of 4 mm in width and 2 mm in length of the sample using the argon gas as a gaseous etchant. To measure the time required to etch each of these layers, the vacuum level in the XPS measurement device is set to 1.0×10⁻⁸ mbar. Monochromator Al Kα (1486.6 eV) is used as an X-ray source. The anode power is set to 72 W, the anode voltage is set to 12 kV, and the voltage of argon ion beams is set to 1 kV. For example, the K-Alpha model manufactured by Thermo Scientific Inc. may be used as the XPS measurement device.

Etch rates of the first light-shielding layer 21 and the second light-shielding layer 22 measured by etching these layers with argon gas as a gaseous etchant are calculated from the thicknesses of these layers and the time required to etch each of these layers.

The etching rate of the second light-shielding layer 22 measured by etching with argon gas as a gaseous etchant may be 0.4 Å/s or more and 0.5 Å/s or less. The etching rate may be 0.41 Å/s or more. The etching rate may be 0.5 Å/s or less. The etching rate may be 0.47 Å/s or less. The etching rate may be 0.45 Å/s or less. In this case, a density of a grain boundary of an upper portion of the light-shielding film 20 may be low, and the light stability (light resistance, i.e., anti-oxidation from light) property of the light-shielding film 20 can be improved.

The etching rate of the first light-shielding layer 21 measured with argon gas as a gaseous etchant may be 0.56 Å/s or more. The etching rate may be 0.58 Å/s or more. The etching rate may be 0.6 Å/s or more. The etching rate may be 1 Å/s or less. The etching rate may be 0.8 Å/s or less. In this case, when the light-shielding film 20 is patterned, it is possible to form a side of the patterned light-shielding film 20 to be substantially perpendicular to the upper surface of the substrate and prevent the etching rate of the light-shielding film 20 from being excessively lowered.

According to one embodiment, the etching rate of the second light-shielding film 20 measured during etching with chlorine-based gas as an etchant may be controlled. Accordingly, it is possible to apply a thinner resist film on the light-shielding film during patterning of the light-shielding film 20, and suppress the resist pattern film from collapsing in patterning of the light-shielding film 20.

A method of measuring the etching rate of the light-shielding film 20 with a chlorine-based gas as an etchant gas will be described below.

First, a TEM image of the light-shielding film 20 is obtained to measure the thickness of the light-shielding film 20. A method of measuring the TEM image on the light-shielding film 20 is as described above and thus will not be redundantly described here.

Thereafter, an etching time is measured by etching the light-shielding film 20 with the chlorine-based gas as a gaseous etchant. The chlorine-based gas contains 90 to 95 vol % chlorine gas and 5 to 10 vol % oxygen gas (percent by volume). An etching rate of the light-shielding film 20 measured during etching with a chlorine-based gas as an etchant gas is calculated from a measured thickness and etching time of the light-shielding film 20.

The etching rate of the light-shielding film 20 measured during etching with the chlorine-based gas as an etchant may be 1.3 Å/s or more. The etching rate may be 1.6 Å/s or more. The etching rate may be 1.7 Å/s or more. The etching rate may be 3 Å/s or less. The etching rate may be 2 Å/s or less. In this case, when the light-shielding film 20 is patterned, a resist film having a relatively thin thickness can be applied on the light-shielding film 20, thereby realizing a more elaborate light-shielding film pattern.

### Composition of Light-Shielding Film

In an embodiment, the amount of each element of each layer of a light-shielding film may be controlled in consideration of reactivity with respect to exposure light, light extinction property, etching characteristics, and the like of the light-shielding film.

The second light-shielding layer 22 may include a transition metal and oxygen. The second light-shielding layer 22 may include the transition metal at 50 at % or more. The second light-shielding layer 22 may include the transition metal at 55 at % or more. The second light-shielding layer 22 may include the transition metal at 60 at % or more. The second light-shielding layer 22 may include the transition metal at 65 at % or more. The second light-shielding layer 22 may include 80 at % or less of the transition metal. The second light-shielding layer 22 may include 75 at % or less of the transition metal.

The second light-shielding layer 22 may include oxygen at 10 at % or more. The second light-shielding layer 22 may include oxygen at 12 at % or more. The second light-shielding layer 22 may include oxygen at 30 at % or less. The second light-shielding layer 22 may include 25 at % or less of oxygen. The second light-shielding layer 22 may include 20 at % or less of oxygen.

In this case, a degree of oxidation of the transition metal in the second light-shielding layer 22 may be controlled to reduce the reactivity of the atoms of the transition metal when light is emitted on the light-shielding film and to allow the second light-shielding layer 22 to have a stable light-shielding property. In addition, an etching rate of the second light-shielding layer 22 when the second light-shielding layer 22 is etched by the etching gas may be controlled so that a side surface of a light-shielding pattern achieved from the light-shielding film 20 may be formed to be substantially perpendicular to a surface of the light-transmitting substrate.

The second light-shielding layer 22 may further include nitrogen. The second light-shielding layer 22 may further include carbon.

The second light-shielding layer 22 may include 3 at % or more of nitrogen. The second light-shielding layer 22 may include 5 at % or more of nitrogen. The second light-shielding layer 22 may include 20 at % or less of nitrogen. The second light-shielding layer 22 may include 15 at % or less of nitrogen.

The second light-shielding layer 22 may include 1 at % or more of carbon. The second light-shielding layer 22 may include 10 at % or less of carbon.

According to this embodiment, the etching rate of each layer in the light-shielding film 20 can be easily adjusted to a predetermined range.

The first light-shielding layer 21 may include a transition metal, oxygen, and nitrogen. The first light-shielding layer 21 may include 20 at % or more of a transition metal. The first light-shielding layer 21 may include 25 at % or more of a transition metal. The first light-shielding layer 21 may include 30 at % or more of a transition metal. The first light-shielding layer 21 may include 35 at % or more of a transition metal. The first light-shielding layer 21 may include 60 at % or less of a transition metal. The first light-shielding layer 21 may include 55 at % or less of a transition metal. The first light-shielding layer 21 may include 50 at % or less of a transition metal.

The first light-shielding layer 21 may include 20 at % or more of oxygen. The first light-shielding layer 21 may include 25 at % or more of oxygen. The first light-shielding layer 21 may include 30 at % or more of oxygen. The first light-shielding layer 21 may include 50 at % or less of oxygen. The first light-shielding layer 21 may include 45 at % or less of oxygen. The first light-shielding layer 21 may include 40 at % or less of oxygen.

The first light-shielding layer 21 may include 3 at % or more of nitrogen. The first light-shielding layer 21 may include 7 at % or more of nitrogen. The first light-shielding layer 21 may include 20 at % or less of nitrogen. The first light-shielding layer 21 may include 15 at % or less of nitrogen.

The first light-shielding layer 21 may include 5 at % or more of carbon. The first light-shielding layer 21 may include 10 at % or more of carbon. The first light-shielding layer 21 may include 25 at % or less of carbon. The first light-shielding layer 21 may include 20 at % or less of carbon.

In this case, the first light-shielding layer 21 may impart excellent light extinction properties to the light-shielding film 20. In addition, by controlling the etching rate of the first light-shielding layer 21, a sophisticated light-shielding pattern film can be achieved.

An absolute value obtained by subtracting the atomic percent amount of the transition metal in the first light-shielding layer 21 from the amount of the transition metal in the second light-shielding layer 22 may be 15 at % or more. The absolute value may be 20 at % or more. The absolute value may be 25 at % or more. The absolute value may be 45 at % or less. The absolute value may be 40 at % or less. The absolute value may be 35 at % or less. In this case, the etching characteristics of each layer of the light-shielding film 20 may be controlled such that a side surface of the patterned light-shielding film 20 is substantially perpendicular to the surface of the light-transmitting substrate.

The transition metal may include at least one of Cr, Ta, Ti, and Hf. According to one example, the transition metal may be Cr.

The amount of each element of each layer of the light-shielding film 20 may be measured through a depth profile using XPS(X-ray Photoelectron Spectroscopy). Specifically, a sample is prepared by processing the blank mask 100 into a dimension of 15 mm in width and 15 mm in length. Thereafter, the sample is placed in an XPS measurement device, and an area having a dimension of 4 mm in width and 2 mm in length located in a central region of the sample is etched to measure the amount of each element of each layer.

For example, the amount of each element of each thin film may be measured by the K-alpha model manufactured by Thermo Scientific Inc.

### Thickness of Light-Shielding Film

According to one example, a ratio of the thickness of the second light-shielding layer 22 to the thickness of the light-shielding film 20 may be in a range of 0.05 to 0.15. In another example, the thickness ratio may be 0.07 or more. In yet another example, the thickness ratio may be 0.12 or less.

The thickness of the first light-shielding layer 21 may be 25 nm or more. The thickness may be 30 nm or more. The thickness may be 35 nm or more. The thickness may be 40 nm or more. The thickness may be 65 nm or less. The thickness may be 60 nm or less. The thickness may be 55 nm or less. The thickness may be 50 nm or less.

The second light-shielding layer 22 may have a thickness of 2 nm or more. The thickness may be 5 nm or more. The thickness may be 20 nm or less. The thickness may be 15 nm or less. The thickness may be 10 nm or less.

In this case, the shape of a light-shielding pattern film obtained by patterning the light-shielding film 20 may be easily controlled, and the light-shielding film 20 may have a light-shielding property sufficient to substantially block exposure light.

The light-shielding film 20 may have a thickness of 27 nm or more. The thickness may be 35 nm or more. The thickness may be 40 nm or more. The thickness may be 45 nm or more. The thickness may be 85 nm or less. The thickness may be 75 nm or less. The thickness may be 65 nm or less. The thickness may be 57 nm or less. In this case, the light-shielding film 20 may exhibit a stable light-blocking effect.

### Optical Characteristics of Light-Shielding Film

The optical density of a light-shielding film 20 with respect to light having a wavelength of 193 nm may be 1.3 or more. The optical density may be 1.4 or more.

The transmittance of the light-shielding film 20 with respect to light having a wavelength of 193 nm may be 1% or less. The transmittance may be 0.5% or less. The transmittance may be 0.2% or less.

In this case, the light-shielding film 20 may help effectively block the transmission of exposure light.

The optical density and transmittance of the light-shielding film 20 may be measured using a spectroscopic ellipsometer. For example, the optical density and transmittance of the light-shielding film 20 may be measured using an MG-Pro model manufactured by NANO-VIEW Co., Ltd.

### Other Thin Films

FIG. 3 is a diagram for conceptually illustrating an example of a blank mask according to the present disclosure. The following description is made with reference to FIG. 3.

A phase shift film 30 may be disposed between a light-transmitting substrate 10 and a light-shielding film 20 of a blank mask 100. The phase shift film 30 is a thin film that attenuates the intensity of exposure light passing therethrough and adjusts the phase difference of the exposure light to substantially offset light diffracted at an edge of a transfer pattern.

A phase difference of the phase shift film 30 with respect to light having a wavelength of 193 nm may be 170° to 190°. The phase difference of the phase shift film 30 with respect to the light having the wavelength of 193 nm may be 175° to 185°.

A transmittance of the phase shift film 30 with respect to the light having the wavelength of 193 nm may be in a range of 3% to 10%. The transmittance of the phase shift film 30 with respect to the light having the wavelength of 193 nm may be in a range of 4% to 8%.

In this case, diffracted light that may occur at an edge of a pattern film may be effectively suppressed.

An optical density of a thin film including the phase shift film 30 and the light-shielding film 20 with respect to light having a wavelength of 193 nm may be 3 or more. The optical density of the thin film including the phase shift film 30 and the light-shielding film 20 with respect to the light having a wavelength of 193 nm may be 5 or less. In this case, the thin film may effectively suppress the transmission of exposure light.

The phase difference and transmittance of the phase shift film 30 and the optical density of the thin film including the phase shift film 30 and the light-shielding film 20 may be measured using a spectroscopic ellipsometer. For example, the spectroscopic ellipsometer may be the MG-Pro model manufactured by NANO-VIEW Co., Ltd.

The phase shift film 30 may include a transition metal and silicon. The phase shift film 30 may include a transition metal, silicon, oxygen, and/or nitrogen. In one example, the transition metal may be molybdenum.

A hard mask (not shown) may be positioned on the light-shielding film 20. The hard mask may function as an etching mask when a pattern of the light-shielding film 20 is etched. The hard mask may include silicon, nitrogen, and/or oxygen.

A resist film (not shown) may be positioned on the light-shielding film 20. The resist film may be formed in contact with an upper surface of the light-shielding film 20. The resist film may be formed in contact with an upper surface of another film on the light-shielding film 20.

A resist pattern film may be formed by irradiating electron beams on the resist film and developing the resist film. The resist pattern film may function as an etching mask when a pattern of the light-shielding film 20 is etched.

A positive resist may be applied as the resist film. A negative resist may be applied as the resist film. For example, an FEP255 model manufactured by Fuji Corp. may be applied for the resist film.

### Photomask

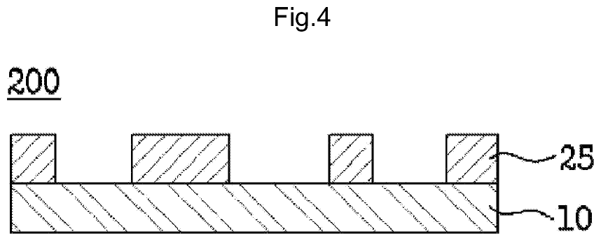

FIG. 4 is a diagram illustrating an example of a photomask according to another embodiment of the present disclosure. The following description will refer to FIG. 4.

A photomask 200 according to another embodiment of the present disclosure includes a light-transmitting substrate 10 and a light-shielding pattern film 25 disposed on the light-transmitting substrate 10.

The light-shielding pattern film 25 includes a transition metal and oxygen.

When light with a wavelength of 172 nm and an intensity of 10 kJ/cm² is radiated on the light-shielding pattern film 25, the time required for scum formation is 120 minutes or more.

The light-transmitting substrate 10 included in the photomask 200 is as described above, and thus a description thereof will be omitted here.

The light-shielding pattern film 25 may be formed by patterning the light-shielding film 20 described above.

The description of the layer structure, physical properties, composition, and the like of the light-shielding pattern film 25 are substantially the same as those of the light-shielding film 20 described above, and thus will not be redundantly described here.

### Method of Manufacturing Light-Shielding Film

An example of a method of manufacturing a blank mask according to an embodiment of the present disclosure includes a preparation operation of disposing a sputtering target including a transition metal and a light-transmitting substrate in a sputtering chamber, a film-forming operation of forming a light-shielding film on the light-transmitting substrate, and a heat treatment operation of heat-treating the light-shielding film.

In the preparation operation, a target may be selected to form the light-shielding film in consideration of the composition of the light-shielding film.

At least one selected from the group consisting of Cr, Ta, Ti, Hf and a combination thereof may comprise 90 wt % or more of the sputtering target by composition. At least one selected from the group consisting of Cr, Ta, Ti, Hf and a combination thereof may comprise 95 wt % or more of the sputtering target. At least one selected from the group consisting of Cr, Ta, Ti, Hf and a combination thereof may comprise 99 wt % or more of the sputtering target. At least one selected from the group consisting of Cr, Ta, Ti, Hf, and a combination thereof may comprise 100 wt % or less of the sputtering target.

Cr may comprise 90% or more of the sputtering target by weight. Cr may comprise 95% or more of the sputtering target by weight. Cr may comprise 99% or more of the sputtering target by weight. Cr may comprise 99.9% or more of the sputtering target by weight. Cr may comprise 99.97 wt % or more of the sputtering target by weight. Cr may comprise 100% or less of the sputtering target by weight.

In the preparation operation, a magnet may be disposed in the sputtering chamber. The magnet may be positioned on a surface opposite to a surface on which sputtering occurs in the sputtering target.

The film-forming operation may involve a first light-shielding layer forming process of forming a first light-shielding layer on the light-transmitting substrate, and a second light-shielding layer forming process of forming a second light-shielding layer on the first light-shielding layer.

In the film-forming operation, different sputtering process conditions may be applied to each layer included in the light-shielding film. Specifically, various process conditions, such as an atmosphere gas composition, electric power supplied to the sputtering target, and a film-formation time, may be applied to each layer of the light-shielding film in consideration of crystallization characteristics, light extinction property, and etching characteristics required for each layer.

Atmospheric gas may include a reactive gas. A reactive gas is a gas containing an element that constitutes a thin film to be formed.

The atmospheric gas may include a sputtering gas that is ionized in a plasma atmosphere and thus collides with a target.

The atmospheric gas may further include a stress control gas for controlling the stress of the thin film to be obtained.

The sputtering gas may include at least one selected from the group consisting of Ar, Ne, Kr, and a combination thereof. According to one example, the sputtering gas may be Ar.

The stress control gas may include He. The stress control gas may be He.

The reactive gas may include a gas containing nitrogen. For example, the gas containing nitrogen may be N₂, NO, NO₂, N₂O, N₂O₃, N₂O₄, N₂O₅, or the like. The reactive gas may include a gas containing oxygen. The gas containing oxygen may be, for example, O₂, CO₂, or the like. The reactive gas may include a gas containing nitrogen and a gas containing oxygen. The reactive gas may include a gas containing both nitrogen and oxygen. For example, the gas containing both nitrogen and oxygen may be NO, NO₂, N₂O, N₂O₃, N₂O₄, N₂O₅, or the like.

A power source supplying electric power to the sputtering target may be a direct-current (DC) power supply or a radio-frequency (RF) power supply.

In the film-forming operation, the crystal grain boundary density of the surface of the light-shielding film to be formed may be controlled by adjusting the temperature of the light-transmitting substrate to be within a predetermined range of temperature. The formation of a grain boundary of the transition metals may be effectively suppressed by quickly controlling the heat generation of the thin film to be formed.

The temperature of the light-transmitting substrate may be controlled by a cooling process through cooling means. Specifically, heat generated during a sputtering process may be removed by circulating a refrigerant having a controlled temperature around the perimeter of the substrate or outside the sputtering chamber. A fluid, e.g., water, may be applied as the refrigerant.

The temperature of the light-transmitting substrate may be measured by a temperature measurement sensor.

In the film-forming operation, the temperature of the light-transmitting substrate may be 10° C. or higher. The temperature may be 15° C. or higher. The temperature may be 20° C. or higher. The temperature may be 40° C. or less. The temperature may be 35° C. or less. The temperature may be 30° C. or less.

During the operation of forming the first light-shielding layer, the temperature of the light-transmitting substrate may be 10° C. or higher. The temperature may be 15° C. or higher. The temperature may be 20° C. or higher. The temperature may be 40° C. or less. The temperature may be 35° C. or less. The temperature may be 30° C. or less.

During the operation of forming the second light-shielding layer, the temperature of the light-transmitting substrate may be 10° C. or higher. The temperature may be 15° C. or higher. The temperature may be 20° C. or higher. The temperature may be 40° C. or less. The temperature may be 35° C. or less. The temperature may be 30° C. or less.

By controlling the temperature, it is possible to suppress the migration of ions of the transition metal when light is irradiated on the light-shielding film.

During the operation of forming the first light-shielding layer, the electric power supplied to the sputtering target may be set to a range of 1.5 kW to 2.5 kW. In another example, the electric power supplied to the sputtering target may be set to a range of 1.6 kW to 2 kW.

During the operation of forming the first light-shielding layer, the atmospheric gas may contain 10% or more of the sputtering gas by volume. The atmospheric gas may include 15 vol % or more of the sputtering gas. The atmospheric gas may include 30 vol % or less of the sputtering gas. The atmospheric gas may include 25 vol % or less of the sputtering gas.

The atmospheric gas may include 30 vol % or more of the reactive gas. The atmospheric gas may include 35 vol % or more of the reactive gas. The atmospheric gas may include 40 vol % or more of the reactive gas. The atmospheric gas may include 60 vol % or less of the reactive gas. The atmospheric gas may include 55 vol % or less of the reactive gas. The atmospheric gas may include 50 vol % or less of the reactive gas.

The atmospheric gas may include 25 vol % or more of a gas containing oxygen. The atmospheric gas may include 30 vol % or more of the gas containing oxygen. The atmospheric gas may include 45 vol % or less of the gas containing oxygen. The atmospheric gas may include 40 vol % or less of the gas containing oxygen.

The atmospheric gas may include 5 vol % or more of a gas containing nitrogen. The atmospheric gas may include 20 vol % or less of the gas containing nitrogen. The atmospheric gas may include 15 vol % or less of the gas containing nitrogen.

The atmospheric gas may include 20 vol % or more of the stress control gas. The atmospheric gas may include 25 vol % or more of the stress control gas. The atmospheric gas may include 30 vol % or more of the stress control gas. The atmospheric gas may include 50 vol % or less of the stress control gas. The atmospheric gas may include 45 vol % or less of the stress control gas. The atmospheric gas may include 40 vol % or less of the stress control gas.

During the operation of forming the first light-shielding layer, the atmosphere gas may be under a pressure of 0.8×10⁻⁴ torr to 1.5×10⁻³ torr. The pressure may be in a range of 1×10⁻³ torr to 1.5×10⁻³ torr.

In this case, the formed first light-shielding layer may help the light-shielding film to have a sufficient light extinction property. In addition, the first light-shielding layer may help accurately control the shape of a light-shielding pattern film obtained from the light-shielding film.

The first light-shielding layer forming operation may be performed for approximately 200 seconds to 300 seconds. The first light-shielding layer forming operation may be performed for 230 seconds to 280 seconds. In this case, the first light-shielding layer may have a thickness sufficient to add a sufficient light-shielding property to the light-shielding film.

During the process of forming the second light-shielding layer, the electric power to be supplied to the sputtering target may be set in a range of 1 to 2 kW. The electric power may be set to 1.2 to 1.7 kW.

During the process of forming the second light-shielding layer, the atmospheric gas contains 35 vol % or more of the sputtering gas. The atmospheric gas may include 40 vol % or more of the sputtering gas. The atmospheric gas may include 45 vol % or more of the sputtering gas. The atmospheric gas may include 50 vol % or more of the sputtering gas. The atmospheric gas may include 75 vol % or less of the sputtering gas. The atmospheric gas may include 70 vol % or less of the sputtering gas. The atmospheric gas may include 65 vol % or less of the sputtering gas. The atmospheric gas may include 60 vol % or less of the sputtering gas.

The atmospheric gas may include 20 vol % or more of the reactive gas. The atmospheric gas may include 25 vol % or more of the reactive gas. The atmospheric gas may include 30 vol % or more of the reactive gas. The atmospheric gas may include 35 vol % or more of the reactive gas. The atmospheric gas may include 60 vol % or less of the reactive gas. The atmospheric gas may include 55 vol % or less of the reactive gas. The atmospheric gas may include 50 vol % or less of the reactive gas.

The atmospheric gas may include 20 vol % or more of a gas containing nitrogen. The atmospheric gas may include 25 vol % or more of the gas containing nitrogen. The atmospheric gas may include 30 vol % or more of the gas containing nitrogen. The atmospheric gas may include 35 vol % or more of the gas containing nitrogen. The atmospheric gas may include 60 vol % or less of the gas containing nitrogen. The atmospheric gas may include 55 vol % or less of the gas containing nitrogen. The atmospheric gas may include 50 vol % or less of the gas containing nitrogen.

During the operation of forming the second light-shielding layer, the atmospheric gas may be under a pressure of 2×10⁻⁴ torr to 9×10⁻⁴ torr. The pressure may be in a range of 3×10⁻⁴ torr to 7×10⁻⁴ torr.

In this case, the surface of the light-shielding film may have excellent light stability (light resistance, i.e., anti-oxidation from light), and a fine light-shielding pattern film may be obtained when the light-shielding film is patterned.

The second light-shielding layer forming process may be performed for 10 seconds to 30 seconds. The second light-shielding layer forming process may be performed for 15 seconds to 25 seconds. In this case, when a light-shielding pattern film is obtained by dry etching, a side surface of the light-shielding pattern film may be substantially perpendicular to the surface of the light-transmitting substrate.

In the heat treatment operation, the composition of elements on the surface of the light-shielding film may be controlled by adjusting the temperature of the surface of the light-shielding film and the like. Accordingly, the surface of the light-shielding film may be prevented from being excessively etched by an etching gas while the formation of the transition metal ions may be suppressed when exposure light is emitted on the light-shielding film.

In the heat treatment operation, the temperature of the surface of the light-shielding film may be 150° C. or higher. The temperature may be 200° C. or higher. The temperature may be 220° C. or higher. The temperature may be 400° C. or less. The temperature may be 350° C. or less. The temperature may be 300° C. or less.

The heat treatment operation may be performed for two minutes or more. The heat treatment operation may be performed for five minutes or more. The heat treatment operation may be performed for fifteen minutes or less.

The heat treatment operation may be performed in an atmosphere of dry air. Dry air refers to unsaturated air that does not contain vapor.

In this case, the light stability (light resistance, i.e., anti-oxidation from light) property of the light-shielding film can be improved while the degradation of the etching resistance property of the surface of the light-shielding film is suppressed.

### Method of Manufacturing Semiconductor Device

A method of manufacturing a semiconductor device according to another embodiment of the present disclosure. The method involves a preparation operation of arranging a light source, a photomask, and a semiconductor wafer coated with a resist film, an exposure operation of selectively transmitting light incident from the light source to the semiconductor wafer through the photomask, and a developing operation of developing a pattern on the semiconductor wafer.

The photomask includes a light-transmitting substrate and a light-shielding pattern film on the light-transmitting substrate.

The light-shielding pattern film includes a transition metal and oxygen.

When light with a wavelength of 172 nm and an intensity of 10 kJ/cm² is emitted on the light-shielding pattern film, the time required for scum formation is 120 minutes or more.

In the preparation operation, the light source is a device for generating exposure light with a short wavelength. The exposure light may be light with a wavelength of 200 nm or less. The exposure light may be ArF light with a wavelength of 193 nm.

A lens may be further disposed between the photomask and the semiconductor wafer. The lens has the function of reducing a form of a circuit pattern on the photomask and transferring the circuit pattern to the semiconductor wafer. The type of the lens is not limited as long as the lens can be generally applied to an ArF semiconductor wafer exposure process. For example, the lens may be a lens formed of calcium fluoride (CaF₂).

In the exposure operation, exposure light may be selectively transmitted to the semiconductor wafer through the photomask. In this case, chemical modification may occur in a portion of a resist film on which the exposure light is incident.

In the developing operation, the semiconductor wafer after exposure operation is treated with a developing solution to develop a pattern on the semiconductor wafer. When an applied resist film is a positive resist, the portion of the resist film on which the exposure light is incident may be dissolved due to the developing solution. When an applied resist film is a negative resist, a portion of the resist film on which the exposure light is not incident may be dissolved due to the developing solution. A resist pattern is formed from the resist film through the treatment by the developing solution. A pattern may be formed on the semiconductor wafer using the resist pattern as a mask.

The photomask is as described above, and thus a description thereof is omitted here.

Hereinafter, a specific embodiment will be described in more detail.

### Manufacturing Example: Formation of Light-Shielding Film

Example 1: A quartz light-transmitting substrate with a width of 6 inches, a length of 6 inches, a thickness of 0.25 inches, and a flatness of less than 500 nm was disposed of in a chamber of a DC sputtering device. A chromium (Cr) target was disposed in the chamber so that a target-to-substrate (T/S) distance was 255 mm and an angle between the light-transmitting substrate and a sputtering target was 25 degrees. A magnet was installed on the rear surface of the sputtering target. A refrigerant pipe was installed outside the sputtering chamber to circulate cooling water.

Thereafter, a first light-shielding layer was formed by introducing an atmospheric gas, in which 19 vol % of Ar, 11 vol % of N₂, 36 vol % of CO₂, and 34 vol % of He were mixed, into the chamber under a pressure of 1.2×10⁻³ torr, and performing the sputtering process for 248 seconds by setting the electric power to be supplied to the sputtering target to 1.85 kW, a speed of rotation of the magnet to 113 rpm, and a temperature of the light-transmitting substrate to 24° C.

After the first light-shielding layer was formed, a second light-shielding layer was formed on the first light-shielding layer by introducing an atmospheric gas, in which 57 vol % of Ar and 43 vol % of N₂ were mixed, into the chamber at a pressure of 5.4×10⁻⁴ torr, and performing the sputtering process for 22.5 seconds by setting power to be supplied to the sputtering target to 1.5 kW, the speed of rotation of the magnet to 113 rpm, and a temperature of the light-transmitting substrate to 24° C.

A sample obtained after the formation of the second light-shielding layer was disposed in a heat treatment chamber. Thereafter, heat treatment was performed in an atmosphere of dry air for 10 minutes by setting the surface temperature of the light-shielding film to 250° C.

Comparative Example 1: A chromium target was disposed in a sputtering chamber under the same conditions as in Example 1.

Thereafter, a first light-shielding layer was formed by introducing an atmospheric gas, in which 21 vol % Ar, 11 vol % N₂, 32 vol % CO₂, and 36 vol % He were mixed, into the chamber at a pressure of 9.5×10⁻⁴ torr, and performing the sputtering process for 283 seconds by setting electric power to be supplied to the sputtering target to 1.85 kW, the rotation speed of the magnet to 113 rpm, and a temperature of the light-transmitting substrate to 120° C.

After the first light-shielding layer was formed, a second light-shielding layer was formed on the first light-shielding layer by introducing an atmospheric gas, in which 80 vol % of Ar and 20 vol % N₂ were mixed, into the chamber at a pressure of 4.6×10⁻⁴ torr, and performing the sputtering process for 25 seconds by setting the electric power supplied to the sputtering target to 1.5 kW, the rotation speed of the magnet to 113 rpm, and a temperature of the light-transmitting substrate to 120° C.

A sample obtained after the formation of the second light-shielding layer was disposed in a heat treatment chamber. Thereafter, heat treatment was performed in an atmosphere of dry air for 20 minutes by setting the surface temperature of the light-shielding film to 120° C.

Comparative Example 2: A chromium target was disposed in a sputtering chamber under the same conditions as in Example 1.

Thereafter, a first light-shielding layer was formed by introducing an atmospheric gas, in which 22 vol % Ar, 6 vol % N₂, 33 vol % CO₂, and 39 vol % He were mixed, into the chamber at a pressure of 8.0×10⁻⁴ torr, and performing the sputtering process for 137 seconds by setting the electric power supplied to the sputtering target to 1.85 kW, the rotation speed of the magnet to 113 rpm, and a temperature of the light-transmitting substrate to 120° C.

A second light-shielding layer was formed on the first light-shielding layer by introducing an atmospheric gas, in which 80 vol % Ar and 20 vol % N₂ were mixed, into the chamber at a pressure of 4.7×10⁻⁴ torr, and performing the sputtering process for 20 seconds by setting electric power to be supplied to the sputtering target to 1.5 kW, the rotation speed of the magnet to 113 rpm, and a temperature of the light-transmitting substrate to 120° C.

A third light-shielding layer was formed on the second light-shielding layer by introducing an atmospheric gas, in which 21 vol % Ar, 11 vol % N₂, 32 vol % CO₂, and 36 vol % He were mixed, into the chamber at a pressure of 1.0×10⁻³ torr, and performing the sputtering process for 70 seconds by setting electric power to be supplied to the sputtering target to 1.5 kW, the rotation speed of the magnet to 113 rpm, and a temperature of the light-transmitting substrate to 120° C.

The light-transmitting substrate temperature and the heat treatment temperature and time in the film-forming operation of each of Example 1 and the comparative examples are shown in Table 1 below.

### Evaluation Example: Measurement of Scum Formation Time

A transmission pattern with a constant line width was formed in the light-shielding film of each of the samples according to Example 1 and Comparative Examples 1 and 2. Thereafter, light with a wavelength of 172 nm and an intensity of 10 kJ/cm² was emitted and applied to the surface of the light-shielding film using a UV exposure light accelerator. During the irradiating of the light, an image on the surface of the light-shielding film was measured by an SEM at intervals of 30 minutes to check whether scum was generated on the transmission pattern.

The scum formation times as measured in each of Example 1 and the comparative examples are shown in Table 1.

### Evaluation Example: Measurement of Etching Characteristics of Each Layer of Light-Shielding Film

Two samples of Example 1 were processed to have a size of 15 mm in width and 15 mm in length. Surfaces of the processed samples were treated by Focused Ion Beams (FIBs), and the samples were placed in JEM-2100F HR high-resolution transmission electron microscope from JEOL, Ltd. Transmission Electron Microscope (TEM) images for the samples were taken. The thicknesses of the first light-shielding layer and the second light-shielding layer were calculated from the TEM images.

Thereafter, the length of time required for etching the first light-shielding layer and the length of time required for etching the second light-shielding layer of one of the samples of Example 1 with argon gas as an etchant gas were measured. Specifically, the sample was placed in the K-Alpha model of Thermo Scientific Inc., and the length of time required for etching each layer was measured by etching an area with a dimension of 4 mm in width and 2 mm in length in a central region of the sample with argon gas. To measure the length of time required to etch each layer, the vacuum level in a measurement device was set to 1.0×10⁻⁸ mbar, Monochromator Al Kα (1486.6 eV) was used as an X-ray source, anode power was set to 72 W, an anode voltage was set to 12 kV, and a voltage of argon ion beams was set to 1 kV.

The etch rate of each layer was calculated from the measured thicknesses and etching times of the first and second light-shielding layers.

Etching rates measured with the argon gas in Example 1 are shown in Table 2 below.

### Evaluation Example: Measurement of Thickness and Etching Characteristics of Entire Light-Shielding Film

Samples of Example 1 and the comparative examples were processed to have a size of 15 mm in width and 15 mm in length. Surfaces of the processed samples were treated by FIBs, and the samples were placed in a JEM-2100F HR model transmission electron microscope from JEOL, Ltd. TEM images of the samples were taken. The thickness of each layer of light-shielding films was calculated from the TEM images.

Thereafter, the time required to etch each of the entire light-shielding films was measured by etching the samples of Example 1 and the comparative examples with chlorine gas as an etchant gas using the TETRAX model of a dry etching device of Applied Materials Inc. A gas containing 90 to 95 vol % of chlorine gas and 5 to 10 vol % of oxygen gas was used as the chlorine-based gas. Etch rates of the light-shielding films with respect to the chlorine-based gas were calculated from the thicknesses and etching times of the light-shielding films.

The thickness of each layer of and the etch rates of the light-shielding films of Example 1 and the comparative examples are shown in Table 3 below.

### Evaluation Example: Measurement of Surface of Light-Shielding Film and Composition of Each Layer Thereof

The surface of the light-shielding film of Example 1 and the composition of each layer of the light-shielding films of Example 1 and the comparative examples were measured using XPS analysis. Specifically, samples were prepared by processing blank masks of Example 1 and the comparative examples to have a size of 15 mm in width and 15 mm in length. After arranging the samples in a K-Alpha model measuring device of Thermo Scientific Inc., the amount of each element in a central region having a size of 4 mm in width and 2 mm in length of each of the samples was measured. Thereafter, the central region was etched to measure the amount of each element of each layer.

Measurement results of Example 1 and Comparative Examples 1 and 2 are shown in Table 4 below.

### Evaluation Example: Evaluation of Quenching Property of Light-Shielding Film

Transmittances of the light-shielding films of Example 1 and the comparative examples with respect to light with a wavelength of 193 nm were measured. Specifically, the transmittances of the light-shielding films of the samples with respect to the light of the wavelength of 193 nm were measured using the MG-Pro model, which is a spectroscopic ellipsometer, of NANO-VIEW Co., Ltd.

Measurement results of Example 1 and Comparative Examples 1 and 2 are shown in Table 4 below.

TABLE 1

| | Temperature (° C.) of light- | | | | | |
|---|---|---|---|---|---|---|
| | transmitting substrate | | | | | Time |
| | First | Second | Third | Heat | Heat | required to |
| | light- | light- | light- | treatment | treatment | generate |
| | shielding | shielding | shielding | temperature | time | scum |
| | layer | layer | layer | (° C.) | (minutes) | (minutes) |
| Example 1 | 24 | 24 | — | 250 | 10 | 150 |
| Comparative | 120 | 120 | — | 120 | 20 | 60 |
| Example 1 | | | | | | |
| Comparative | 120 | 120 | 120 | — | — | 90 |
| Example 2 | | | | | | |

TABLE 2

| | Etch rate (Å/s) of first light- | Etch rate (Å/s) of second light- |
|---|---|---|
| | shielding layer measured by | shielding layer measured by |
| | etching first light-shielding | etching second light-shielding |
| | layer with argon gas | layer with argon gas |
| Example 1 | 0.621 | 0.430 |

TABLE 3

| | Thickness of | Thickness of | Thickness of | Etching rate |
|---|---|---|---|---|
| | first light- | second light- | third light- | (Å/s) of |
| | shielding | shielding | shielding | entire light- |
| | layer | layer | layer | shielding |
| | (nm) | (nm) | (nm) | film |
| Example 1 | 47 | 5 | — | 1.7 |
| Comparative | 47 | 5 | — | 1.2 |
| Example 1 | | | | |
| Comparative | 14 | 4 | 30 | 0.9 |
| Example 2 | | | | |

TABLE 4

| | | Cr | C | N | O | Transmittance |
|---|---|---|---|---|---|---|
| | | (at %) | (at %) | (at %) | (at %) | (%) |
| Example 1 | Surface | 38.7 | 15.3 | 3.3 | 42.7 | 0.12 |
| | Second light- | 72 | 4 | 9 | 15 | |
| | shielding layer | | | | | |
| | First light- | 42 | 13 | 9 | 36 | |
| | shielding layer | | | | | |
| Comparative | Second light- | 76 | 1 | 11 | 12 | 0.08 |
| Example 1 | shielding layer | | | | | |
| | First light- | 48 | 11 | 7 | 34 | |
| | shielding layer | | | | | |
| Comparative | Third light- | 60 | 14 | 4 | 22 | 0.05 |
| Example 2 | shielding layer | | | | | |
| | Second light- | 65 | 9 | 6 | 20 | |
| | shielding layer | | | | | |
| | First light- | 38 | 9 | 8 | 45 | |
| | layer shielding | | | | | |

Table 1 shows that a time required to generate scum was measured to be 150 minutes in Example 1 but was measured to be 100 minutes or less in the comparative examples.

A blank mask according to an embodiment may include a light-shielding film with an excellent light-shielding property and have a stable resolution even when an exposure process is repeatedly performed to form a pattern.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation.

Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A blank mask comprising:
a light-transmitting substrate; and
a light-shielding film on the light-transmitting substrate,
wherein the light-shielding film comprises a transition metal and oxygen, and
a scum formation time required to generate scum is 120 minutes or more when light with a wavelength of 172 nm and an intensity of 10 kJ/cm² is applied to the light-shielding film.

2. The blank mask of claim 1, wherein a surface of the light-shielding film comprises transition metal content in an amount of 30 or more and 50 or less atomic percent.

3. The blank mask of claim 1, wherein a surface of the light-shielding film comprises oxygen content in an amount of 35 or more and 55 or less atomic percent.

4. The blank mask of claim 1, wherein the light-shielding film comprises a first light-shielding layer, and a second light-shielding layer on the first light-shielding layer,
wherein an etching rate of the second light-shielding layer measured by etching with argon gas is 0.4 Å/s or more and 0.5 Å/s or less.

5. The blank mask of claim 4, wherein an etching rate of the first light-shielding layer measured by etching with argon gas is 0.56 Å/s or more.

6. The blank mask of claim 1, wherein an etching rate of the light-shielding film measured by etching with chlorine-based gas is 1.3 Å/s or more.

7. The blank mask of claim 1, wherein the light-shielding film comprises a first light-shielding layer, and a second light-shielding layer on the first light-shielding layer,
wherein the second light-shielding layer comprises transition metal content in an amount of 50 or more and 80 or less atomic percent and oxygen content in an amount of 10 or more atomic percent.

8. The blank mask of claim 1, wherein the transition metal comprises one or more selected from the group consisting of: scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), lanthanum (La), hafnium (Hf), tantalum (Ta), tungsten (W), rhenium (Re), osmium (Os), iridium (Ir), platinum (Pt), gold (Au), mercury (Hg), actinium (Ac), rutherfordium (Rf), dubnium (db), seaborgium (Sg), bohrium (Bh), hassium (Hs), meitnerium (Mt), darmstadtium (Ds), roentgenium (Rg), ununbiium (Uub), and a combination thereof.

9. The blank mask of claim 1, wherein the light-shielding film comprises a first light-shielding layer, and a second light-shielding layer on the first light-shielding layer,
wherein a ratio of a thickness of the second light-shielding layer to a thickness of the light-shielding film is in a range of 0.05 or more and 0.15 or less.

10. A photomask obtained from the blank mask of claim 1, the photomask comprising:
the light-transmitting substrate; and
the light-shielding pattern film on the light-transmitting substrate,
wherein the light-shielding pattern film comprises a transition metal and oxygen, and
the scum formation time required to generate scum is 120 minutes or more when light with a wavelength of 172 nm and an intensity of 10 kJ/cm² is applied to the light-shielding pattern film.

11. A method of manufacturing a semiconductor device, the method comprising:
disposing a light source, a photomask, and a semiconductor wafer coated with a resist film;
selectively exposing the semiconductor wafer to light from the light source through the photomask; and
developing a pattern on the semiconductor wafer,
wherein the photomask comprises a light-transmitting substrate and a light-shielding pattern film disposed on the light-transmitting substrate,
the light-shielding pattern film comprises a transition metal and oxygen, and
a scum formation time required to generate scum is 120 minutes or more when light with a wavelength of 172 nm and an intensity of 10 kJ/cm² is applied to the light-shielding pattern film.
